(19) United States
(12) Patent Application Publication
(10) Pub. No.: US 2015/0380612 A1
(43) Pub. Date: Dec. 31, 2015

(54) Color-Tunable Light Emitting Device

(71) Applicant: Toshiba Corporation, Tokyo (JP)

(72) Inventor: Long Yang, Union City, CA (US)

(73) Assignee: TOSHIBA CORPORATION, Minato-ku, Tokyo (JP)

(21) Appl. No.: 14/317,697

(22) Filed: Jun. 27, 2014

(51) Int. Cl. H01L 33/50; H01L 33/62; H01L 27/15

(52) U.S. Cl. CPC H01L 33/50; H01L 27/156; H01L 33/62

(57) ABSTRACT

One aspect of the present invention is directed to a color-tunable light source including a light emitting diode die segmented into a plurality of sub-light emitting diode regions, at least one of the plurality of light emitting regions defining a first zone and at least one of the plurality of light emitting regions defining a second zone, a color conversion material such as phosphor material covering at least a top surface of each light emitting region in the first zone, a first electrical contact connected to a light emitting region in the first zone, and a second electrical contact connected to a light emitting region in the second zone. A current applied to the first electrical contact drives the light emitting regions in the first zone and a second current applied to the second electrical contact drives the light emitting regions in the second zone. In one embodiment the light source further includes a second color conversion material covering each of the light emitting regions in the first zone and the second zone. In another embodiment, the light source further includes a second color conversion material covering at least a top surface of each of the light emitting regions in the second zone.

### FIELD OF THE INVENTION

This invention generally relates to light emitting diodes and more particularly to a color-tunable light emitting diode.

### BACKGROUND OF THE INVENTION

Light emitting diodes, or LEDs, are well-known as energy efficient light sources and have become popular for commercial and residential lighting applications. But a significant challenge in using LEDs for lighting applications is ensuring color uniformity, particular in large-scale projects involving large numbers of LED lamps or fixtures. Even with modern manufacturing techniques having very tight tolerances there are natural variations in materials and processes that determine the photometric properties of LED devices. Material characteristics vary over the surface of a wafer and over the surface of individual LED dies. Due to these natural variations LED manufacturers cannot produce large quantities of white LEDs with uniform color.

White LED devices are typically made by applying a yellow phosphor material to an LED die that produces blue light. Some of the blue light emitted by the LED die is absorbed by the yellow phosphor material and emitted as yellow light, and some of the blue light passes unchanged through the yellow phosphor material. The human eye perceives this combination of blue light and yellow light as white light. The color correlated temperature (CCT) of the white light is determined by the dominant wavelength of the blue light emitted by the LED die and the composition of the yellow phosphor material. A CCT value in the range of 2700-3000K is described as “warm white,” a CCT value in the range of 3500-4000K is described as “neutral white,” and a CCT value in the range of 4500-5500K is described as “cool white.” Unlike other types of light sources, the CCT of LEDs is quite stable over a large intensity range. This is because the amount of phosphor-generated light is nearly linearly proportional to the amount of blue light generated by the LED die. But an LED device with a color temperature of 2700K will look different than another LED device with a color temperature of 3000K even though both are considered to be “warm white.”

The non-uniformity of color among white LED devices presents a challenge for commercial applications where the optimization of the lighting scheme is more important than in typical residential applications. White LED devices from different manufacturers all designated as “warm white” will have variations in color that will be noticeably different in a light installation with large numbers of LED devices. Even purchasing all of the white LED devices for a light installation from a single manufacturer and with the same color temperature rating is no guarantee that all of the devices will produce the exact same color light.

One prior art solution to the problem of non-uniformity of color among white LED devices is to combine warm white (WW), cool white (CW), and neutral white LED devices in a single lamp or fixture. An external driver circuit drives each of the LED devices independently to adjust the mix of WW, CW, and neutral white light and thus the color temperature of the lamp as a whole. For example, the Philips iW MR Gen3 LED lamp has 6 LED devices (emitters), 2 cool white, 2 warm white, and 2 neutral white, and can output light with a color temperature ranging from 2700K to 5700K. But solutions such as this are only practical for larger lamps that can accommodate the multiple LED devices and required driver circuitry. A similar solution is to package multiple LED dies within one LED device (emitter) with external driver circuitry. For example, the LED Engin, Inc. LuxiTune products include 12 or more dies in a single emitter package and can output light with a color temperature ranging from 1600K to 4300K. A drawback of this solution is that controlling the light output of such a large number of dies requires a complex external driver circuit that forces the size of the lamp to be much larger than the emitter itself. The costs of this external circuitry quickly multiply for lighting installation that include hundreds of LED devices. Further, each of the multiple LED dies in the device will have to be monitored for temperature changes and the driving current adjusted accordingly.

Another prior art solution to the problem of non-uniformity of color is to include separate red, blue, and green LED devices in a single lamp or fixture. An external driver circuit drives each of the LED devices independently to adjust the mix of red, green, and blue light to produce a range of colors including various white colors. For example, a greater proportion of red light will produce a warm white color and a greater proportion of blue light will produce a cool white color. Such a lamp provides flexibility in generating white light at different color temperatures, but has the drawback of requiring multiple separate LED devices and more complex driver circuitry. Another drawback of this solution is that the physical distances between the LED devices in the lamp cause the mixed light from the lamp to be non-uniform. The optical axes of the LED devices will be offset from each other, which will cause the light to not mix properly in all directions, producing colored fringing of shadows.

A similar prior art solution includes separate red, blue, and green LED dies in a single package with a diffuse mirror to mix the colored light to produce white light. Adjusting the driving current to each of the separate LEDs tunes the color temperature of the resulting white light. But a significant drawback of these red, blue, and green mixing approaches is that red LEDs (those made from aluminum, gallium, indium, phosphate materials) are much more sensitive to temperature effects than green or blue LEDs (those made from indium gallium nitride materials). Red LEDs also age much faster than blue or green LEDs, and lamps that include red, blue, and green LEDs require circuitry to determine when the aging red LEDs require higher current levels to produce the required light output. Such circuitry includes temperature sensors and a memory for storing the appropriate input current levels for various temperature values.

There is, therefore, an unmet demand for a color-tunable light emitting diode that provides a substantially uniform white light.

### BRIEF DESCRIPTION OF THE INVENTION

One aspect of the present invention is directed to a color-tunable light source including a light emitting diode die segmented into a plurality of light emitting regions, at least one of the plurality of light emitting regions defining a first zone and at least one of the plurality of light emitting regions defining a second zone, a phosphor material covering at least a top surface of each light emitting region in the first zone, a first electrical contact connected to a light emitting region in the first zone, and a second electrical contact connected to a light emitting region in the second zone. A current applied to the first electrical contact drives the light emitting regions in the first zone and a second current applied to the second electrical contact drives the light emitting regions in the second zone. In one embodiment the light source further includes a second phosphor material covering each of the light emitting regions in the first zone and the second zone. In another embodiment, the light source further includes a second phosphor material covering at least a top surface of each of the light emitting regions in the second zone. In one embodiment, the phosphor material covering the light emitting regions in the first zone is configured to produce light having a color correlated temperature of about 2700-3000K and a second phosphor material covering the light emitting regions in the second zone is configured to produce a light having a color correlated temperature of about 4500-5500K. In another embodiment, the light source further includes at least one of the plurality of light emitting regions defining a third zone and a third electrical contact connected to a light emitting region in the third zone, and wherein the phosphor material covering at least the top surface of each the light emitting region in the first zone is a red phosphor material and a second phosphor material covering at least a top surface of each light emitting region in the third zone is a green phosphor material.

Another aspect of the present invention is directed to a color-tunable light source including a light emitting diode die including a plurality of light emitting regions, at least one of the plurality of light emitting regions defining a first zone and at least one of the plurality of light emitting regions defining a second zone, a color conversion material covering at least a top surface of each of the plurality of light emitting regions in the first zone, a first electrical contact connected to a light emitting region in the first zone, and a second electrical contact connected to a light emitting region in the second zone. In one embodiment, the color conversion material is a phosphor material having a color different than the color of light output by the light emitting regions in the second zone. In another embodiment, the color conversion material is a quantum dot material configured to emit light having a color that is different than the color of light output by the light emitting regions in the second zone.

Other aspects and advantages of the invention will be apparent from the description below.

### BRIEF DESCRIPTION OF THE FIGURES

FIG. 1 is a plan view of one embodiment of a light emitting diode die including a plurality of light emitting regions, according to the invention.

FIG. 2A is a plan view of one embodiment of a light emitting diode die including a plurality of light emitting regions with a red phosphor coating covering certain light emitting regions, according to the invention.

FIG. 2B is a cross-sectional view of the light emitting diode die of FIG. 2A, according to the invention.

FIG. 2C is a cross-sectional view of a light emitting diode die with a red phosphor covering certain light emitting regions and a second phosphor coating, according to the invention.

FIG. 3 is a cross-sectional view of one embodiment of a light emitting diode die including a plurality of light emitting regions with a phosphor coating covering certain light emitting regions, according to the invention.

FIG. 4A is a plan view of one embodiment of a light emitting diode die including a plurality of light emitting regions with a red phosphor coating covering certain light emitting regions and a green phosphor coating covering certain other light emitting regions, according to the invention.

FIG. 4B is a plan view of one embodiment of a light emitting diode die including bond pads and a plurality of light emitting regions with a red phosphor coating covering certain light emitting regions and a green phosphor coating covering certain other light emitting regions, according to the invention.

FIG. 5A is a plan view of one embodiment of a light emitting diode die including a plurality of light emitting regions with a cool white phosphor coating certain light emitting regions and a warm white phosphor coating covering certain other light emitting regions, according to the invention.

FIG. 5B is a cross-sectional view of the light emitting diode die of FIG. 5A.

FIG. 6 is a plan view of one embodiment of a light source including a color-tunable light emitting diode, according to the invention.

### DETAILED DESCRIPTION OF THE INVENTION

The present invention will now be discussed with reference to the Figures, wherein like figure reference numerals correspond to like elements.

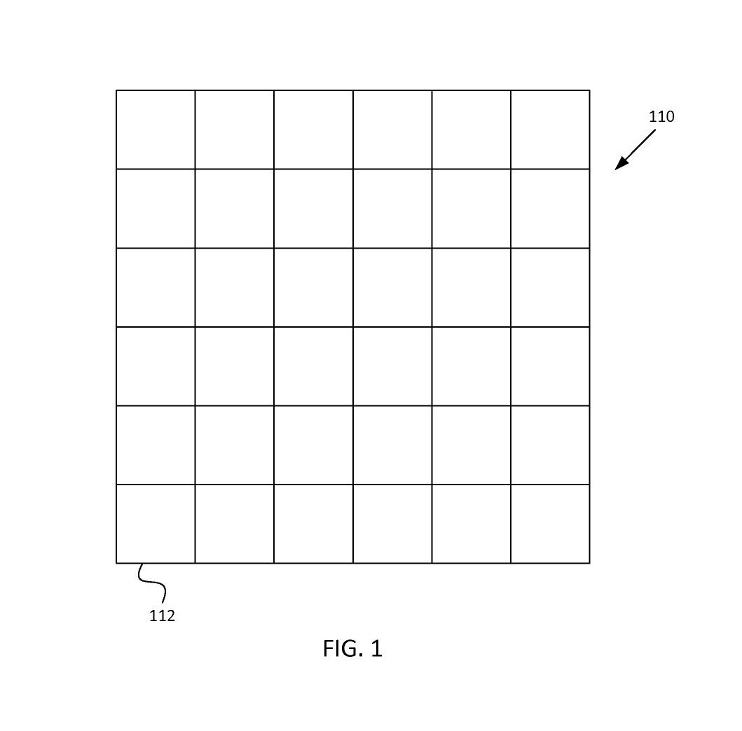

FIG. 1 is a plan view of one embodiment of a light emitting diode die 110 including a plurality of light emitting regions (sub-LEDs or LED segments) 112, according to the invention. LED die 110 is a blue light emitting diode die that has been segmented into a six-by-six array of sub-LEDs 112. In the FIG. 1 embodiment, each sub-LED 112 is a square with each side being 0.1 mm. In other embodiments, LED die 110 may be sub-divided into any number of sub-LEDs and the area of each sub-LED does not need to be symmetrical or uniform across LED die 110. Contacts and electrical connections are not shown in FIG. 1 for ease of illustration. Sub-LEDs 112 may be interconnected in any appropriate fashion, such as in series, in parallel, and various combinations of serial and parallel connections, depending on the configuration of the external driver circuit (not shown)

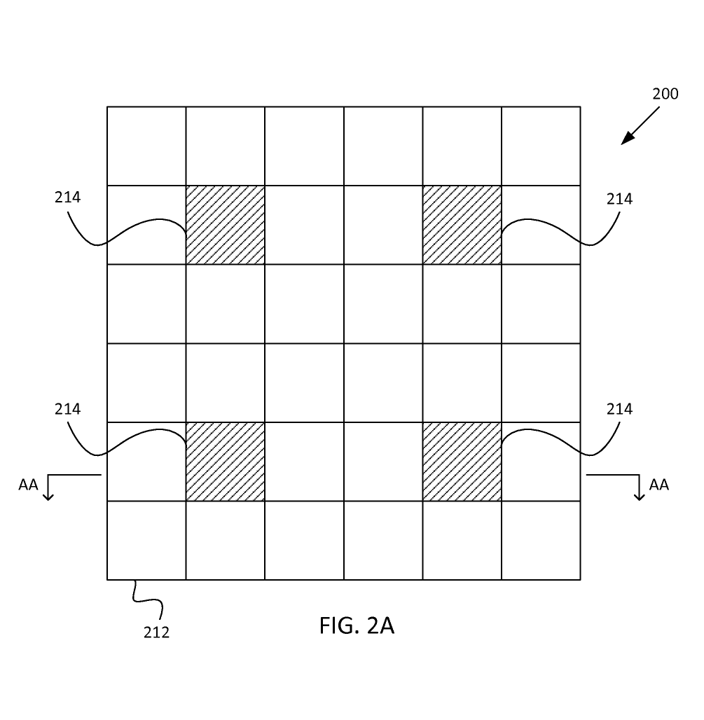

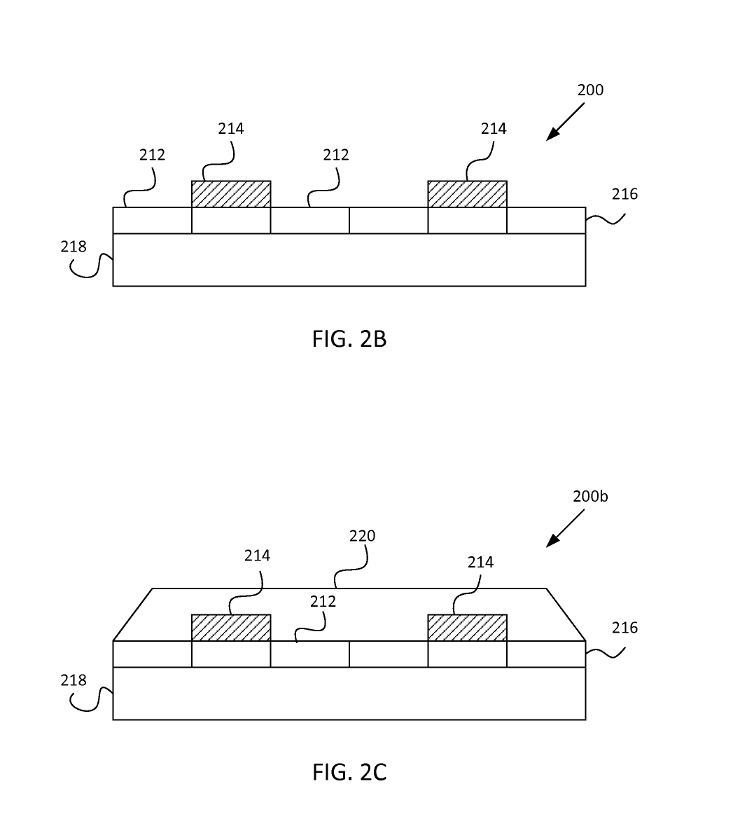

FIG. 2A is a plan view of one embodiment of a light emitting diode die including a plurality of sub-LEDs with a red phosphor coating covering certain sub-LEDs, according to the invention. LED die 200 includes a six-by-six array of sub-LEDs, chosen for illustrative purposes. Four of the sub-LEDs 214 have been covered by a red phosphor material and the remaining sub-LEDs 212 have no phosphor coating. In one embodiment, the red phosphor material is applied to selected ones of the sub-LEDs 214 using a screen-printing process at the wafer level. Other techniques for selectively applying phosphor materials to wafers or individual dies, such as a lift-off technique, are within the scope of the invention. The red phosphor material may be any appropriate nitride-containing red phosphor, for example the RR6436 or LWR6733 phosphors available from Intematix.

In another embodiment, instead of a phosphor material, one or more sub-LEDs may be covered by a different type of color conversion material such as semiconductor nanocrystals, called quantum dots. Quantum dots, for example nanocrystals of cadmium selenide (CdSe), behave like phosphors but can be tuned to radiate light of different colors by changing the physical size of the dots.

The plurality of red phosphor coated sub-LEDs 214 define a first zone of LED die 200 and the plurality of sub-LEDs 212 define a second zone of LED die 200. The sub-LEDs within each zone are electrically connected to each other (connections not shown in FIG. 2A). Any technique for connecting sub-LEDs 212 in series and sub-LEDs 214 in series is within the scope of the invention. The first and second zones can be driven by separate externally applied currents, and are preferably electrically isolated from each other. Each zone includes an electrical contact such as a bond pad or through-substrate via (not shown) to connect that zone to an external driver circuit using a bond wire or solder ball. Although two zones are shown in FIG. 2A, any number of zones is within the scope of the invention.

Red phosphor coated sub-LEDs 214 in the first zone emit red light when driven by current from an external driver circuit (not shown). The amount of red light generated by red phosphor coated sub-LEDs 214 can be modulated by adjusting the applied current to the interconnected sub-LEDs 214. Sub-LEDs 212 in the second zone emit blue light when driven by current from an external driver circuit (not shown). Thus the light emitted by LED die 200 is a mixture of blue light emitted by sub-LEDs 212 (and in some embodiments some residual blue light emitted by sub-LEDs 214) and red light emitted by sub-LEDs 214.

FIG. 2B is a cross-sectional view of the light emitting diode die of FIG. 2A at line AA. LED die 210 includes a substrate 218 and a blue light emitting LED layer 216 that includes sub-LEDs 212 and red phosphor coated sub-LEDs 214. The electrical connections and trenches between the sub-LEDs are not shown in FIG. 2B for ease of illustration.

FIG. 2C is a cross-sectional view of a light emitting diode die 200b with a red phosphor covering certain sub-LEDs and a second phosphor coating 220, according to the invention. Phosphor coating 220 may be a green phosphor material, a yellow phosphor material, a mixture of green and yellow phosphor materials, or a mixture of green, yellow, and red phosphor materials. Phosphor coating 220 may be any appropriate aluminate-, nitride-, or silicate-containing yellow, green, and/or red phosphor material, for example GAL545 or GAL525 phosphors available from Intematix. Phosphor coating 220 can be applied at the wafer level or to each individual LED die 300 after dicing. A benefit of applying phosphor coating 220 at the die level is that the spectrum of the light emitted by LED die 200b can be more closely controlled by adjusting the amount of phosphors in phosphor coating 220. A benefit of applying phosphor coating 220 at the wafer level is lower processing costs.

The ratio of blue light to yellow/green/red light emitted by LED die 200b is substantially fixed after phosphor coating 220 has been applied. The amount of red light (or additional red light if phosphor coating 220 includes a red phosphor material) can be modulated by adjusting the current driving the red phosphor coated sub-LEDs 214, thereby enabling the overall color of the light emitted by LED die 200b to be tuned. Sub-LEDs 212 and red phosphor coated sub-LEDs 214 are made of identical light-emitting materials and are integrated as segments of LED die 200. Thus the temperature dependence of the light emitted by sub-LEDs 212 and sub-LEDs 214 is the same, and no temperature compensation between sub-LEDs 212 and sub-LEDs 214 will be necessary. This uniformity of temperature dependence between sub-LEDs 212 and sub-LEDs 214 improves the color uniformity and color fidelity of LED die 200b.

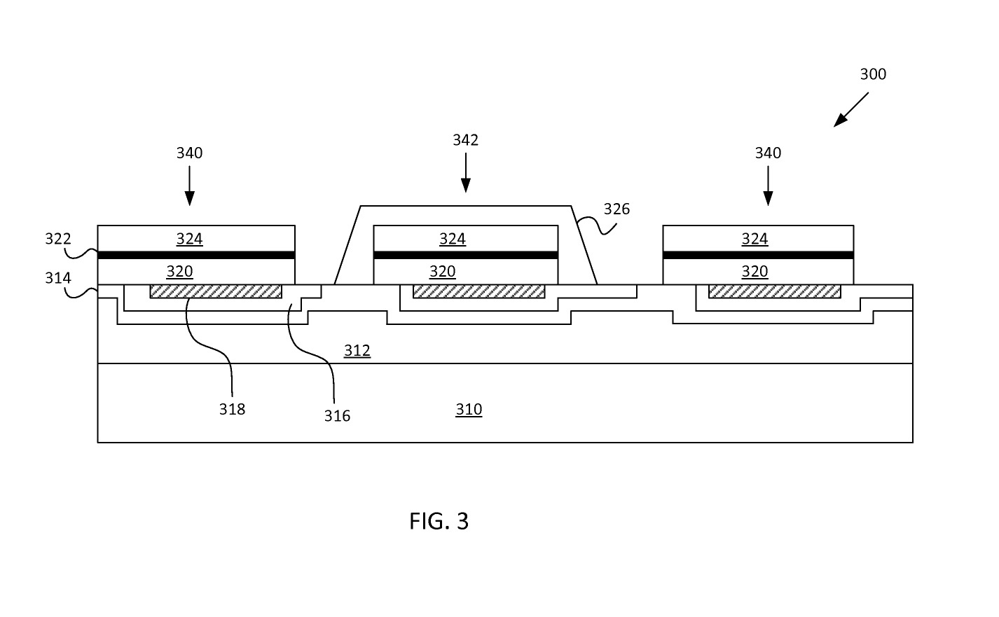

FIG. 3 is a cross-sectional view of an embodiment of a light emitting diode die 300 including a plurality of light emitting regions (sub-LEDs or LED segments). While only three light emitting regions are shown in FIG. 3, an LED die including any number of light emitting regions is within the scope of the invention. LED die 300 includes a handling or carrier substrate 310 and a metal bonding layer 312. On top of metal bonding layer 312 is an insulating layer 314 made of a dielectric material. LED die 300 also includes areas with a barrier metal layer 316, which can be platinum, titanium, titanium-tungsten, or titanium-tungsten-nitride, and areas with a mirror layer 318, which may be a metal layer containing silver. While FIG. 3 shows a vertical flip-chip chip structure, other types of LED structures including lateral chip structures, vertical structures on a transparent substrate, and structures without a metal bonding layer are within the scope of the invention.

Each of sub-LEDs 340 and 342 include a p-type layer 320, an active layer 322, and an n-type layer 324. Sub-LEDs 340 and 342 are separated by trenches etched through layers 320, 322, and 324. Although not shown in FIG. 3, sub-LEDs 340 are connected in series. Contacts and electrical connections between sub-LEDs are not shown in FIG. 3 for ease of illustration. To provide flexibility in routing electrical connections between sub-LEDs, a LED die 300 may include a buried contact layer or a wide trench between sub-LEDs. In one embodiment, LED die 300 may be segmented into a plurality of light emitting regions using the techniques disclosed in U.S. Pat. No. 8,581,267 to Lester et al., the disclosure of which is hereby incorporated by reference. Other techniques for segmenting an LED die into a plurality of light emitting regions are within the scope of the invention. Sub-LED 342 includes a phosphor coating 326. In the FIG. 3 embodiment, phosphor coating 326 covers the top surface and side surfaces of sub-LED 342. In other embodiments, phosphor coating 326 covers only the top surface of sub-LED 342 and a small amount of blue light will be emitted by the side surfaces of sub-LED 342. In the FIG. 3 embodiment, phosphor coating 326 is a red phosphor material. When a driving current is applied to sub-LED 342, sub-LED 342 will emit red-colored light. The ratio of the driving current applied to sub-LEDs 340 and the driving current applied to sub-LED 342 determines the overall color of the light emitted by LED die 300. Through the selection of particular phosphor materials and driving currents, the color of the light emitted by LED die 300 can be varied along a desired color range such as a blackbody curve on a chromaticity diagram.

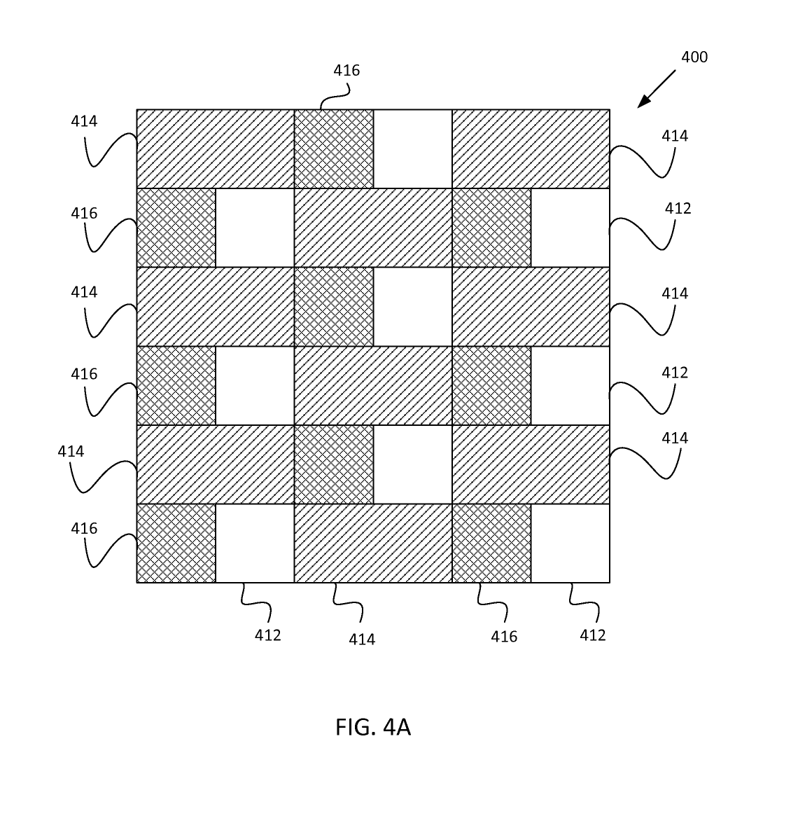

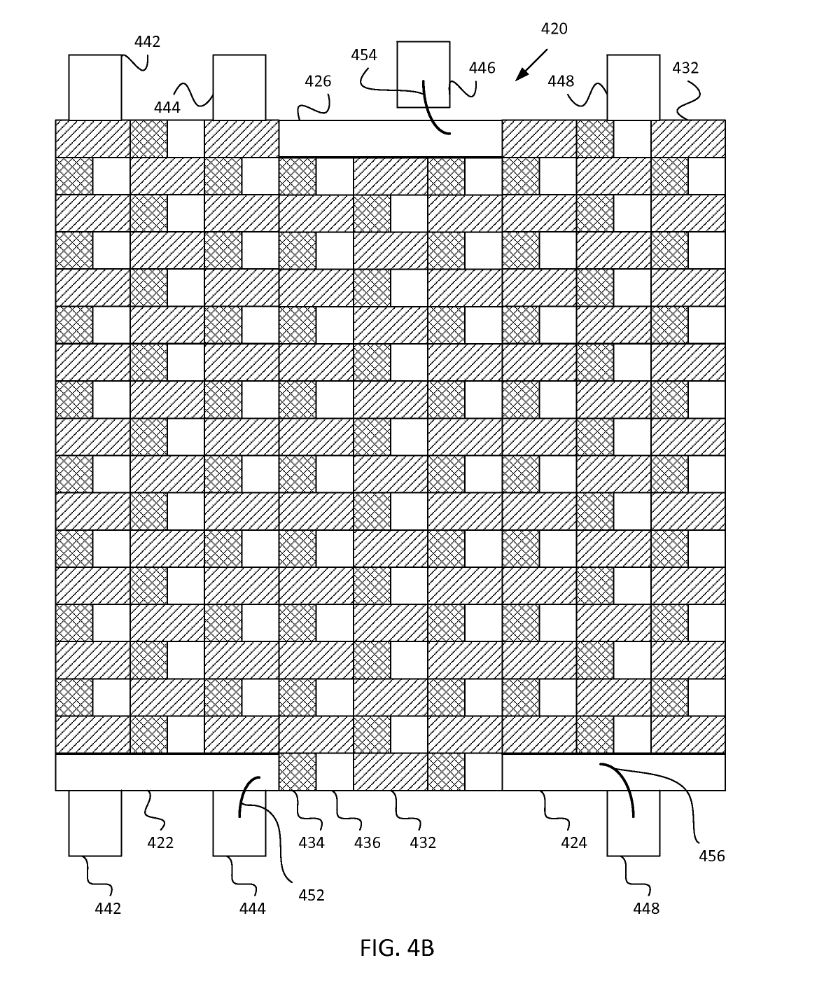

FIG. 4A is a plan view of one embodiment of a light emitting diode 400 including a plurality of sub-LEDs with a red phosphor coating covering certain sub-LEDs 414 and a green phosphor coating covering certain other sub-LEDs 416, according to the invention. LED 400 has been segmented into an array of sub-LEDs 412, 414, and 416. Contacts and electrical connections are not shown in FIG. 4A for ease of illustration. Sub-LEDs 412 have no phosphor coating and are electrically connected together in series to define a first zone of LED 400. Sub-LEDs 414 have a red phosphor coating and are electrically connected together in series to define a second zone of LED 400. Sub-LEDs 416 have a green phosphor coating and are electrically connected together in series to define a third zone of the LED 400. In the FIG. 4A embodiment no yellow or green phosphor coating has been applied over the entire LED 400. Each zone is electrically connected to a bond pad (not shown) to connect that zone to an external driver circuit using a bond wire or solder ball. Although three zones are shown in FIG. 4, any number of zones is within the scope of the invention. Further, other area ratios and shapes of sub-LEDs with no phosphor coating, with a red phosphor coating, and with a green phosphor coating are within the scope of the invention.

In the FIG. 4A embodiment, sub-LEDs 412, red phosphor coated sub-LEDs 414, and green phosphor coated sub-LEDs 416 can be independently electrically driven which enables the color of light emitted by LED 400 to be tuned to almost any possible color. Thus LED 400 would be highly desirable for signage and display applications.

Sub-LEDs 412, red phosphor coated sub-LEDs 414, and green phosphor coated sub-LEDs 416 are made of the same light-emitting materials because they are segments of a single LED die. The difference in temperature dependence of different phosphor materials is generally small. Thus the temperature dependence of the light emitted by sub-LEDs 412, sub-LEDs 414, and sub-LEDs 416 is substantially the same, and no temperature compensation between sub-LEDs 412, sub-LEDs 414, and sub-LEDs 416 will be necessary. This substantial uniformity of temperature dependence between sub-LEDs 412, sub-LEDs 414, and sub-LEDs 416 improves the color uniformity and color fidelity of LED 400.

FIG. 4B is a plan view of one embodiment of a light emitting diode including a plurality of sub-LEDs with a red phosphor coating covering certain sub-LEDs 432 and a green phosphor coating covering certain other sub-LEDs 434 and bond pads, according to the invention. The plurality of red phosphor coated sub-LEDs 432 define a first zone of LED 420, the plurality of green phosphor coated sub-LEDs 434 define a second zone, and the plurality of sub-LEDs 436 with no phosphor coating define a third zone of LED 420. The sub-LEDs within each zone are electrically connected to each other (connections not shown in FIG. 4B). In one embodiment, sub-LEDs 432 are connected in series, sub-LEDs 434 are connected in series, and sub-LEDs 436 are connected in series. The first, second, and third zones can be driven by separate externally applied currents, and are preferably electrically isolated from each other. A bond pad 422 is connected to the series-connected sub-LEDs 436 of the third zone. A bond wire 452 connects bond pad 422 to an electrical connection 444 on a mounting board, which can be connected to an external driver circuit (not shown) to drive the sub-LEDs 436 in the third zone. Similarly, a bond pad 424 is connected to the series-connected red phosphor coated sub-LEDs 432 in the first zone and a bond pad 426 is connected to the series-connected green phosphor coated sub-LEDs 434 in the second zone. A bond wire 456 connects bond pad 424 to an electrical connection 448 on the mounting board, which can be connected to an external driver circuit (not shown) to drive the sub-LEDs 432 in the first zone. A bond wire 454 connects bond pad 426 to an electrical connection 446 on the mounting board, which can be connected to an external driver circuit (not shown) to drive the sub-LEDs 434 in the second zone. A ground connection 442 on the mounting board is connected to LED 420 through the substrate. In other embodiments, the ground connection can be provided on the top surface of LED 420. In other embodiments, electrical connections between each of the zones of sub-LEDs and a mounting board can be made using through-substrate vias. Although three zones are shown in FIG. 4B, any number of zones is within the scope of the invention.

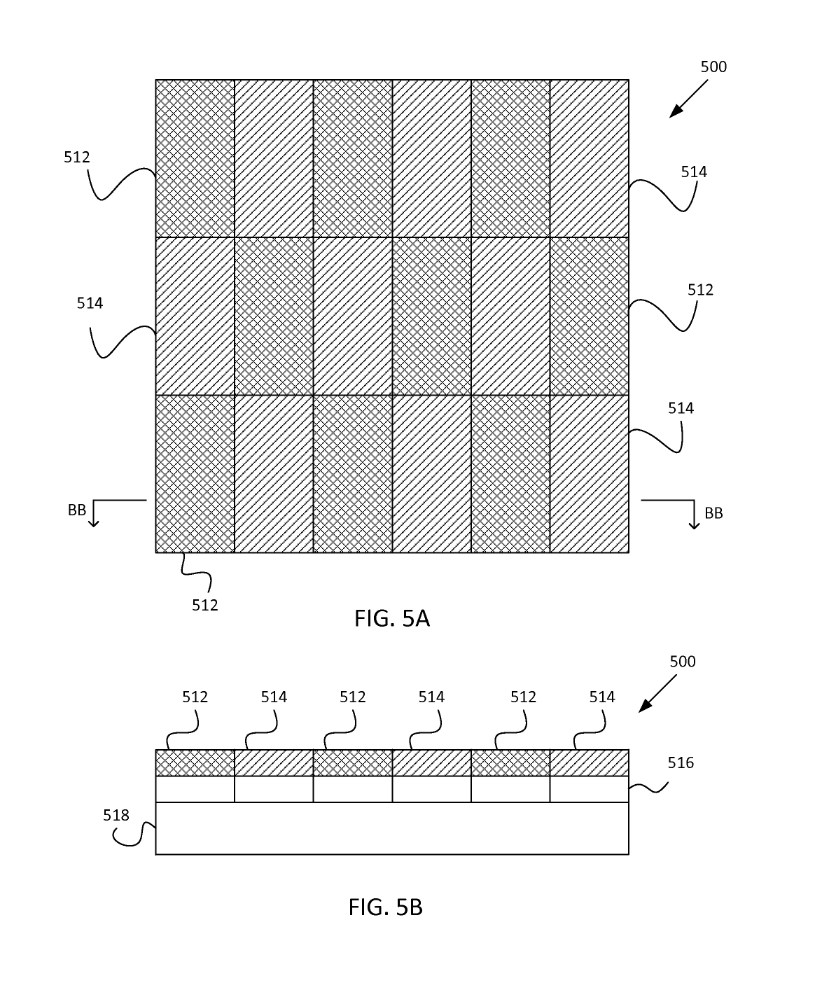

FIG. 5A is a plan view of one embodiment of a light emitting diode 500 including a plurality of sub-LEDs with a cool white phosphor coating certain sub-LEDs 512 and a warm white phosphor coating covering certain other sub-LEDs 514, according to the invention. LED 500 includes a three-by-six array of sub-LEDs. In other embodiments, LED 500 may be sub-divided into any number of sub-LEDs and the area of each sub-LED does not need to be symmetrical or uniform across LED 500. Bond pads and electrical connections are not shown in FIG. 5A for ease of illustration. Sub-LEDs 512 are coated with a phosphor material that will produce light with a color correlated temperature of about 2700-3000K (cool white light) and are electrically connected in series to define a cool-white zone of LED 500. The cool white phosphor may be a particular yellow phosphor or a blend of different colored phosphors selected to achieve a desired color rendering index (CRI). Sub-LEDs 514 are coated with a phosphor material that will produce light with a color correlated temperature of about 4500-5500K (warm white light) and are electrically connected in series to define a warm white zone of LED 500. The warm white phosphor may be a particular yellow phosphor or a blend of different colored phosphors. Each zone includes a bond pad (not shown) to connect that zone to an external driver circuit using a bond wire or solder ball. Although two zones are shown in FIG. 5A, any number of zones is within the scope of the invention.

FIG. 5B is a cross-sectional view of the light emitting diode 500 of FIG. 5A at line BB. LED 500 includes a substrate 518 and a blue LED layer 516 that includes cool white phosphor coated sub-LEDs 512 and warm white phosphor coated sub-LEDs 514. The electrical connections and trenches between the sub-LEDs are not shown in FIG. 5B for ease of illustration. By adjusting the ratio of current driving cool white phosphor coated sub-LEDs 512 and warm white phosphor coated sub-LEDs 514 the color of light emitted by LED 500 can be tuned between a maximum cool (i.e., “coolest”) white color-correlated temperature (about 5500K) and a maximum warm (i.e., “warmest”) white color-correlated temperature (about 2700K).

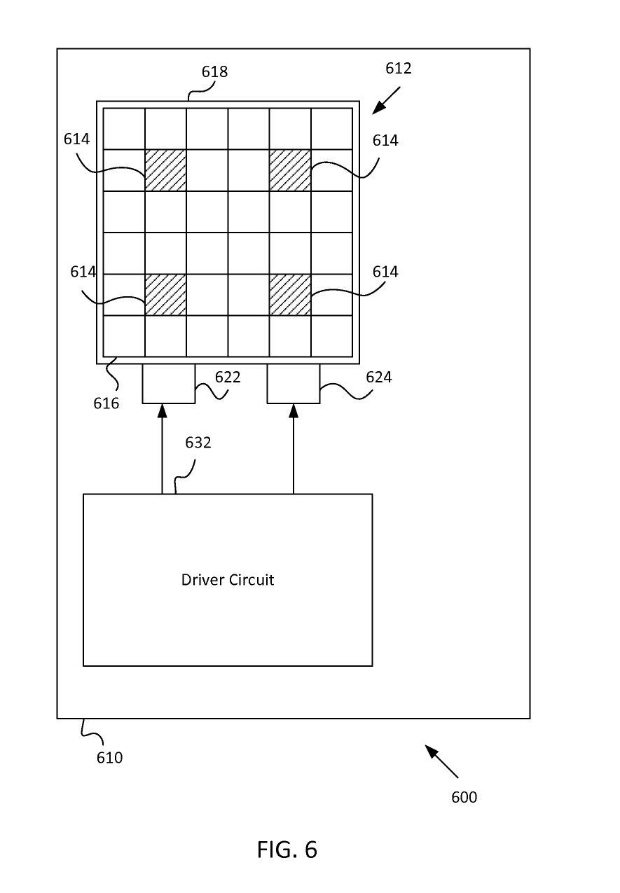

FIG. 6 is a plan view of one embodiment of a light source 600 including a color-tunable light emitting diode 612, according to the invention. Light source 600 includes a color-tunable light emitting diode 612 and an external driver circuit 632 disposed on a mounting board 610. LED 612 includes a plurality of sub-LEDS including sub-LEDs 616 and sub-LEDs 614. The top surface of sub-LEDs 614 are covered with a red phosphor material. The plurality of red phosphor coated sub-LEDs 614 define a first zone of LED 612 and are electrically connected to each other in series. Sub-LEDs 616 define a second zone of LED 612 and are electrically connected to each other in series. The first and second zones are preferably electrically isolated from one another. A yellow phosphor coating 618 covers each of the sub-LEDs 614 and 616 of LED 612.

A connector 622 on mounting board 610 is electrically connected to one of the series-connected red phosphor coated sub-LEDs 614. In the FIG. 6 embodiment, a through via (not shown) in a substrate of LED 612 connects one sub-LED 614 with connector 622. A connector 624 on mounting board 610 is electrically connected to one of the series-connected sub-LEDs 616. In the FIG. 6 embodiment, a second through via (not shown) in the substrate of LED 612 connects one of sub-LEDs 616 with connector 624. Driver circuit 632 provides a first current to connector 622 to drive the red phosphor coated sub-LEDs 614 in the first zone and provides a second current to connector 624 to drive the sub-LEDs 616 in the second zone. The color of light output by light source 600 can be controlled by adjusting the ratio of current applied to the sub-LEDs in each zone. For example, by increasing the amount of current applied to connector 622, driver circuit 632 increases the amount of red light output by LED 612. Driver circuit 632 may be embodied as a single integrated circuit, multiple integrated circuits, or any other appropriate configuration of integrated circuits and/or discrete components capable of outputting a plurality of variable currents. The selection of particular current values can be done by the manufacturer of light source 600 based on a requirement for a light source with a fixed consistent color, or can by controlled by an end user of light source 600 through an external control for a light source that is color-tunable by the end user.

Other objects, advantages and embodiments of the various aspects of the present invention will be apparent to those who are skilled in the field of the invention and are within the scope of the description and the accompanying Figures. For example, but without limitation, structural or functional elements might be rearranged, or method steps reordered, consistent with the present invention. Similarly, principles according to the present invention, and methods and systems that embody them, could be applied to other examples, which, even if not specifically described here in detail, would nevertheless be within the scope of the present invention.

What is claimed is:

1. A color-tunable light source comprising:
a light emitting diode die segmented into a plurality of light emitting regions,
at least one of the plurality of light emitting regions defining a first zone and at least one of the plurality of light emitting regions defining a second zone;
a phosphor material covering at least a top surface of each light emitting region in the first zone;
a first electrical contact connected to a light emitting region in the first zone; and
a second electrical contact connected to a light emitting region in the second zone

2. The color-tunable light source of claim 1, further comprising a second phosphor material covering each of the plurality of light emitting regions in the first and second zones.

3. The color-tunable light source of claim 1, wherein the phosphor material covering at least the top surface of each light emitting region in the first zone has a color that is different than the color of light output by the light emitting diode die.

4. The color-tunable light source of claim 3, further comprising a second phosphor material covering each of the plurality of light emitting regions in the first and second zones, the second phosphor material having a color that is different than the color of light output by the light emitting diode die and the color of the phosphor material covering at least the top surface of each light emitting region in the first zone.

5. The color-tunable light source of claim 1, further comprising a second phosphor material covering at least a top surface of each light emitting region in the second zone.

6. The color-tunable light source of claim 5, wherein the phosphor material covering at least the top surface of each light emitting regions in the first zone is a phosphor material configured to produce light having a color correlated temperature of about 2700-3000K and the second phosphor material covering at least a top surface of each light emitting region in the second zone is a phosphor material configured to produce light having a color correlated temperature of about 4500-5500K.

7. The color-tunable light source of claim 1, wherein at least one of the light emitting regions defines a third zone, and further comprising a third phosphor material covering at least a top surface of each light emitting region in the third zone and a third electrical contact connected to a light emitting region in the third zone.

8. The color-tunable light source of claim 7, wherein the phosphor material covering at least the top surface of each light emitting region in the first zone has a color different than the color of light emitted by the light emitting diode die and the third phosphor material covering at least the top surface of each light emitting region in the third zone has a color different than the color of light emitted by the light emitting diode die and different than the color of the phosphor material covering at least the top surface of each light emitting region in the first zone.

9. The color-tunable light source of claim 1, wherein the light emitting regions in the first zone are electrically connected together and the light emitting regions in the second zone are electrically connected together.

10. The color-tunable light source of claim 1, wherein a current applied to the first electrical contact drives the light emitting regions in the first zone and a second current applied to the second electrical contact drives the light emitting regions in the second zone.

11. The color-tunable light source of claim 7, wherein a current applied to the first electrical contact drives the light emitting regions in the first zone, a second current applied to the second electrical contact drives the light emitting regions in the second zone, and a third current applied to the third electrical contact drives the light emitting regions in the third zone.

12. The color-tunable light source of claim 1, further comprising:
a mounting board with the light emitting diode die disposed thereon;
an electrical connector coupled to the first electrical contact;
a second electrical connector coupled to the second electrical contact; and
a driver circuit disposed on the mounting board and coupled to the first and second electrical connectors, the driver circuit configured to provide a first variable current to the first electrical contact and a second variable current to the second electrical contact.

13. A color-tunable light source comprising:
a light emitting diode die including a plurality of light emitting regions,
at least one of the plurality of light emitting regions defining a first zone and at least one of the plurality of light emitting regions defining a second zone,
a color conversion material covering at least a top surface of each of the plurality of light emitting regions in the first zone;
a first electrical contact connected to a light emitting region in the first zone; and
a second electrical contact connected to a light emitting region in the second zone.

14. The color-tunable light source of claim 13, wherein the color conversion material is a quantum dot material configured to emit a color different than the color of light output by the light emitting regions in the second zone.

15. The color-tunable light source of claim 13, wherein the color conversion material is a phosphor material having a color different than the color of light output by the light emitting regions in the second zone.

16. The color-tunable light source of claim 13, further comprising a second color conversion material covering each of the plurality of light emitting regions in the first and second zones, the second color conversion material having a color that is different than the color of the color conversion material covering at least the top surface of each light emitting region in the first zone and different than the color of the light output by the light emitting regions in the second zone.

17. The color-tunable light source of claim 15, wherein at least a top surface of each light emitting region in the second zone is covered by a second color conversion material having a color different than the color of the color conversion material covering at least the top surface of each light emitting region in the first zone.

18. The color-tunable light source of claim 17, wherein the color conversion material covering at least the top surface of each light emitting region in the first zone is a phosphor material configured to produce light having a color correlated temperature of about 2700-3000K and the second color conversion material covering at least the top surface of each light emitting region in the second zone is a phosphor material configured to produce light having a color correlated temperature of about 4500-5500K.

19. The color-tunable light source of claim 13, wherein at least one of the light emitting regions defines a third zone, and further comprising a second color conversion material covering at least a top surface of each light emitting region in the third zone, the second color conversion material having a color different than the color of the color conversion material covering at least the top surface of each the light emitting region in the first zone and different than the color of light output by the light emitting regions in the second zone, and further comprising a third electrical contact connected to a light emitting region in the third zone.

20. The color-tunable light source of claim 19, wherein the color conversion material covering at least the top surface of each light emitting region in the first zone is a first phosphor material having a first color that is different than the color of the light emitted by the light emitting regions in the second zone, and the second color conversion material is a second phosphor material having a second color that is different than the first color and different than the color of the light emitted by the light emitting regions in the second zone.

21. The color-tunable light source of claim 19, wherein the color conversion material covering at least the top surface of each light emitting region in the first zone is a first quantum dot material configured to emit light having a first color that is different than the color of the light emitted by the light emitting regions in the second zone, and the second color conversion material is a second quantum dot material configured to emit light having a second color that is different than the first color and different than the color of light emitted by the light emitting regions in the second zone.

22. The color-tunable light source of claim 13, wherein the light emitting regions in the first zone are electrically connected together and the light emitting regions in the second zone are electrically connected together.

23. The color-tunable light source of claim 13, wherein a current applied to the first electrical contact drives the light emitting regions in the first zone and a second current applied to the second electrical contact drives the light emitting regions in the second zone.

24. The color-tunable light source of claim 19, wherein a current applied to the first electrical contact drives the light emitting regions in the first zone, a second current applied to the second electrical contact drives the light emitting regions in the second zone, and a third current applied to the third electrical contact drives the light emitting regions in the third zone.

25. The color-tunable light source of claim 13, further comprising:
a mounting board with the light emitting diode die disposed thereon;
an electrical connector coupled to the first electrical contact;
a second electrical connector coupled to the second electrical contact; and
a driver circuit disposed on the mounting board and coupled to the first and second electrical connectors, the driver circuit configured to provide a first variable current to the first electrical contact and a second variable current to the second electrical contact.
